(19) United States
(12) Patent Application Publication
(10) Pub. No.: US 2006/0285566 A1
(43) Pub. Date: Dec. 21, 2006

(54) Surface-emitting laser diode with tunnel junction and fabrication method

(75) Inventor: Nobuaki Ueki, Kanagawa (JP)

Correspondence Address: OLIFF & BERRIDGE, PLC, P.O. BOX 19928, ALEXANDRIA, VA, 22320, US

(73) Assignee: Fuji Xerox Co., Ltd., Tokyo (JP)

(21) Appl. No.: 11/261,671

(22) Filed: Oct. 31, 2005

(30) Foreign Application Priority Data
Jun. 15, 2005 (JP) 2005-175433

(51) Int. Cl. H01S 5/00

(52) U.S. Cl. 372/45.01; 372/46.01

(57) ABSTRACT

A surface emitting semiconductor laser diode includes a semiconductor substrate, a first reflective film provided on the semiconductor substrate, a second reflective film provided above the first reflective film, an active region, a tunnel junction region, and a current funneling layer. The active region, the tunnel junction region, and the current funneling layer are provided in series between the first and second reflective films, the active region being interposed by the tunnel junction region and the current funneling layer.

### BACKGROUND OF THE INVENTION

1. Field of the Invention

This invention relates to surface-emitting laser diodes with tunnel junctions and fabrication methods thereof, which are used for light sources of optical information processing or high-speed optical communication.

2. Description of the Related Art

In recent years, attention has been attracted to surface emitting laser diodes, in particular, to Vertical-Cavity Surface-Emitting Laser diodes (hereinafter, referred to as VCSEL) in the technical fields of the optical communication and optical storage.

VCSEL has excellent characteristics that are not provided by conventional edge-emitting laser diodes. For example, VCSEL have low threshold current and low power consumption. An optical spot is easily obtainable. The device can be tested at the wafer level. The structure can be integrated in a two-dimensional array configuration. Expectations for VCSEL having the afore-mentioned advantages are raised as a low-end light source in the communications field.

The optical communication with optical fibers has been used in mainly mid- and long-distance data transfer (ranging from several kilometers to several tens kilometers). The conventional optical communication employs the single-mode optical fiber with silica as a material and the distributed feedback (DFB) laser having an oscillation peak in the long wavelength range at 1.31 μm or 1.55 μm. The laser in this long-wavelength range exhibits excellent characteristics of “low dispersion and extremely small transmission loss”. Nevertheless, the wavelength has to be controlled strictly. This demands temperature control of the device and causes a problem that downsizing is difficult. In addition, the production volume of the optical fibers is still small, as compared to the consumer products, largely because telecommunications carriers are the users of the optical fibers. Therefore, the laser diodes are considered costly devices.

These days, owing to a growing rate of the Internet access with asymmetric digital subscriber line (ADSL) or cable TV (CATV) at home, it is possible to transmit large-volume data as much as dozens of times, much larger than ever before. Along with the popularization of the Internet access, demands on the large-volume data transmission will be further increased. The optical fibers will definitely be available at home in the near future.

In the short-distance communication (raging from several meters to several hundred meters), however, it can be said an over-specification in view of transmittable distance to use both the single-mode optical fiber and the DFB laser. The high price is also disturbs in spreading. It is considered economical to employ a combination of a costly optical fiber such as multimode silica fiber or plastic optical fiber (POF) together with a short-wavelength range (1 μm or less) that gives good performance when used with the afore-mentioned fibers. VCSEL is becoming attractive for the above-described applications.

In the mid- and long-distance communication, on the other hand, the single-mode optical fiber and the DFB laser are still used. However, the demands for cost reduction in the mid- and long-distance communication will apparently increase the demand for the lasers in the inexpensive long-wavelength range (at 1.31 μm or 1.55 μm) exhibiting a superior cost performance. This is the reason VCSELs attract interests instead of the edge-emitting laser diodes, the yield of which is low. In fact, VCSELs in the long-wavelength range have more problems than those in the short-wavelength range. Therefore, it is still impossible to replace the edge-emitting laser diodes.

There have been proposed structures of VCSEL in the long-wavelength range that exceeds 1 μm in the oscillation wavelength. One structure employs a GaInNAs-based material lattice matched to a GaAs substrate, and another structure is a hybrid structure that includes an InGaAsP-based material in lattice matched to an InP substrate and further includes either a semiconductor multi-film reflector or dielectric multi-film reflector of further another material.

When the VCSEL employs the GaInNAs-based material as disclosed in Japanese Laid-Open Patent Publication No. 10-303515, the GaInNAs-based material is used for a quantum well layer of active layer, whereas AlGaAs/GaAs-based material, which has proved the performance in the short-wavelength range, is used for the multi-film that forms a reflector, a spacer layer, a contact layer, or the like. Accordingly, VCSEL can be fabricated in a relatively small number of processes, that is, after the epitaxial growth is implemented on the GaAs substrate, a current funneling region and electrodes are formed thereon. In other words, it is convenient because the material used for the quantum well layer of the existent short-wavelength VCSEL is changed from GaAs to GaInNAs. Therefore, many studies and experiments have been made and this is the closest to practical use in the long-wavelength VCSELs.

On the other hand, when fabricating the long-wavelength laser diode in which the InGaAsP-based material is used for the quantum well layer, generally, the InP substrate is used to form the lattice matched to the afore-mentioned material. However, a multilayer has to be as thick as at least 50 periods in one of the reflectors to enhance the reflectance, when fabricating the VCSEL with the InGaAsP-based material. This is caused by the characteristics of the refractive index of the InGaAsP-based material, which does not largely change relative to the relative proportions, unlike the refractive index of the AlGaAs-based material. The film having a large number of periods increases the device resistance value and degrades the heat dissipation capacity. It is not desirable in view of the reliability. That is to say, it is considered difficult to fabricate the reflector almost completely reflective, namely, 99 percent at least, by epitaxially growing the InP substrate lattice matched, in the long-wavelength VCSEL having the InGaAsP-based material.

In order to address the afore-mentioned problem, in the hybrid structure with the InGaAsP-based material as disclosed in U.S. Pat. No. 5,835,521, the reflectors are separately fabricated from the neighboring region of the active region, and then are bonded together in a later process. This is called substrate fusion bonding. The substrate fusion bonding makes it possible to bond the semiconductor substrates that cannot form a lattice matched structure, enabling various applications.

In the hybrid structure, however, a discontinuous interface is created between the active region into which the current is injected and the reflectors. The discontinuous interface is low in distinctness as compared to the interface of crystal growth. The carriers that travel through the discontinuous interface are trapped to the level formed in the interface. In most cases, this results in the nonradiative recombination that the carriers are changed to thermal outputs. There are few cases where the reflectors are used for current injection.

Generally, another structure, known as intracavity type, is employed. This structure includes a current path that bypasses the reflectors. However, even in this case, the current funneling region is separately necessary. Accordingly, the techniques for the selective etch or tunnel junction are also utilized together.

Japanese Laid-Open Patent Publication No. 10-321952 and Japanese Laid-Open Patent Publication No. 2002-134835 disclose the VCSELs in which the tunnel junction region is arranged in series between top and bottom semiconductor Bragg reflectors. This eliminates the necessity of p-type semiconductor Bragg reflector having a high light absorption and high resistance. N-type semiconductor Bragg reflectors are used for top and bottom reflectors to reduce the threshold current or the like. U.S. Pat. No. 6,515,308B1 also discloses the structure in which the tunnel junction region is interposed between the top and bottom reflectors in the nitride-based VCSEL.

Japanese Laid-Open Patent Publication No. 2004-247728 describes the tunnel junction structure, which is applied to the VCSEL having the first mirror and the second mirror composed of the n-type semiconductor layers and the active layer interposed therebetween. This structure enables reduction of the p-type semiconductor material that significantly absorbs lights.

U.S. Pat. No. 6,760,357B1 discloses the VCSEL in which multiple active regions, the oxide layer, and the tunnel junction are arranged in series between the first and second mirrors provided on the substrate.

Additionally, M. H. M. Reddy et al., “Selectively Etched Tunnel Junction for Lateral Current and Optical Confinement in InP-Based Vertical Cavity Lasers,” Journal of Electronic Materials, Vol. 33, Pages 118-122, 2004 discloses the long-wavelength VCSEL in which the selective etch and the tunnel junction are combined. In the InP-based VCSEL, the currents in the lateral direction and lights are confined by using the selective etch. E. Hallet al., “Increased Lateral Oxidation Rates of AlInAs on InP Using Short-Period Super lattices,” Journal of Electronic Materials, Vol. 29, Pages 1100-1104, 2000 discloses the method for selectively oxidizing the super lattices and describes the oxidation rate in short-period super lattices of AlAs and InAs provided on InP.

It is to be noted that the structure having GaInNAs-based material, even if the material used for the quantum well active layer and the thickness thereof are controlled as much as possible, there is the problem in that it is difficult to increase the oscillation wavelength up to 1.31 μm, namely, zero dispersion of optical fiber, without sacrificing the reliability or electric or optical characteristics. Light absorption increases as the carrier concentration is increased in the p-type DBR layer, causing degradation in the luminous efficiency. There are drawbacks for practical use.

On the other hand, in the hybrid structure as disclosed in U.S. Pat. No. 5,835,521, the tunnel junction is electrically separated from the surrounding region to define the current injection region. On this account, the selective etch, selective oxidation, crystal regrowth, or the like are employed. Accordingly, the quality of this region decides the characteristics of the laser.

The semiconductor layer that forms the tunnel junction region has extremely high impurity concentration of approximately 1×10²⁰ cm⁻³, and has characteristics that the dopant is easily diffused by temperature rise. Nevertheless, the increase in temperature cannot be avoided when the impurity region or the periphery thereof are processed in the etch, oxidation, and crystal regrowth so as to form the current funneling region. Therefore, the impurity concentration is easy to change in the periphery of the semiconductor layer that forms the tunnel junction region, affecting the process repeatability, specifically, the etch rate, oxidation rate, or crystal growth rate.

As described in U.S. Pat. No. 6,760,357B1, if the tunnel junction region and the current funneling region are closely provided, the impurities diffused from the tunnel junction region change the impurity concentration of the semiconductor layer in the current funneling region. This makes it difficult to provide the oxidized region with repeatability.

On the VCSEL, the current funneling region plays an important role in deciding the characteristics of the whole device, yet the low repeatability in process causes the variations in the diameter of the opening provided in the current funneling region. As a result, the characteristics vary depending on the process lot, which might degrade the mass productivity.

When the carrier concentration of the semiconductor layer is high in the light-passing region, including the tunnel junction region, the light is absorbed by free carriers and the luminous efficiency is degraded. In contrast, Japanese Laid-Open Patent Publication No. 2004-247728 describes the third layer, which is arranged adjacently to the tunnel junction region so as to suppress the diffusion of heavily doped zinc. This third layer reduces the amount of the p-type semiconductor material that absorbs the lights, and improves the luminous efficiency of the VCSEL. However, Japanese Laid-Open Patent Publication No. 2004-247728 does not describe in detail how the current funneling region is created. The current may not be confined especially, as so-called simple pillar structure, yet ineffective recombination will be increased and the luminous efficiency will not be enhanced.

As described, there has not been available the long-wavelength VCSEL that exhibits sufficient characteristics in view of the structure.

### SUMMARY OF THE INVENTION

The present invention has been made in view of the above circumstances and provides a long-wavelength VCSEL with excellent characteristics and high repeatability in mass production and the fabrication method thereof that eliminates complex processes.

According to one aspect of the present invention, there may be provided a surface emitting semiconductor laser diode including a semiconductor substrate; a first reflective film provided on the semiconductor substrate; a second reflective film provided above the first reflective film; an active region; a tunnel junction region; and a current funneling layer. The active region, the tunnel junction region, and the current funneling layer may be provided in series between the first and second reflective films, the active region being interposed by the tunnel junction region and the current funneling layer.

According to another aspect of the present invention, there may be provided a module having the above-mentioned surface emitting semiconductor laser diode.

According to another aspect of the present invention, there may be provided an optical transmission apparatus including a module; and a transmission device that transmits a laser beam emitted from the module. The module may include the above-mentioned surface emitting semiconductor laser diode.

According to another aspect of the present invention, there may be provided a free space optical transmission apparatus including a module; and a transmission device that transmits a light emitted from the module. The module may include the above-mentioned surface emitting semiconductor laser diode.

According to another aspect of the present invention, there may be provided an optical transmission system including a module; and a transmission device that transmits a laser beam emitted from the module. The module may include the above-mentioned surface emitting semiconductor laser diode.

According to another aspect of the present invention, there may be provided a free space optical transmission system including a module; and a transmission device that transmits a light emitted from the module. The module may include the above-mentioned surface emitting semiconductor laser diode.

According to another aspect of the present invention, there may be provided a fabrication method of a surface emitting semiconductor laser diode having a semiconductor substrate, a first reflective film provided on the semiconductor substrate, a second reflective film provided above the first reflective film, an active region, a tunnel junction region, and a current funneling layer provided in series between the first reflective film and the second reflective film, the fabrication method including preparing first and second substrates, the first substrate having a semiconductor layer in which the tunnel junction region and the current funneling layer being respectively epitaxially grown to interpose the active region, the first reflective film being epitaxially grown on the second substrate; bonding the first and second substrates so that the first reflective film faces the semiconductor layer; removing the first substrate; and forming the second reflective film on the semiconductor layer.

### BRIEF DESCRIPTION OF THE DRAWINGS

Embodiments of the present invention will be described in detail based on the following figures, wherein:

FIG. 1 is a sectional-view of a VCSEL in accordance with a first embodiment of the present invention;

FIG. 2 is a cross-sectional view of the VCSEL in accordance with a second embodiment of the present invention;

FIGS. 3A through 5C are cross-sectional views illustrating a configuration and fabrication processes of the VCSEL in accordance with the first embodiment of the present invention;

FIG. 6 is a cross-sectional view of a VCSEL chip, which is incorporated into a package;

FIG. 7 is a cross-sectional view of another package;

FIG. 8 is a cross-sectional view of an optical transmission apparatus to which the package or module shown in FIG. 6 is applied;

FIG. 9 is a view illustrating a configuration of a space transmission system to which the package or module shown in FIG. 7 is applied;

FIG. 10 is a view illustrating a configuration of the optical transmission system to which VCSEL is used as the light source;

FIG. 11 is a view illustrating an appearance of the optical transmission apparatus;

FIGS. 12A and 12B schematically show internal configurations of the optical transmission apparatuses; and

FIGS. 13 and 14 show image transmission systems with the use of the optical transmission apparatus.

### DESCRIPTION OF THE EMBODIMENTS

A description will now be given, with reference to the accompanying drawings, of embodiments of the present invention. On a surface-emitting laser diode in accordance with the embodiments of the present invention, a post structure may be formed on a semiconductor substrate, and a laser beam is emitted from a top of the post structure. In this specification, “mesa” is used as a synonym for “post” and “film” is used as a synonym for “layer”.

### Embodiments

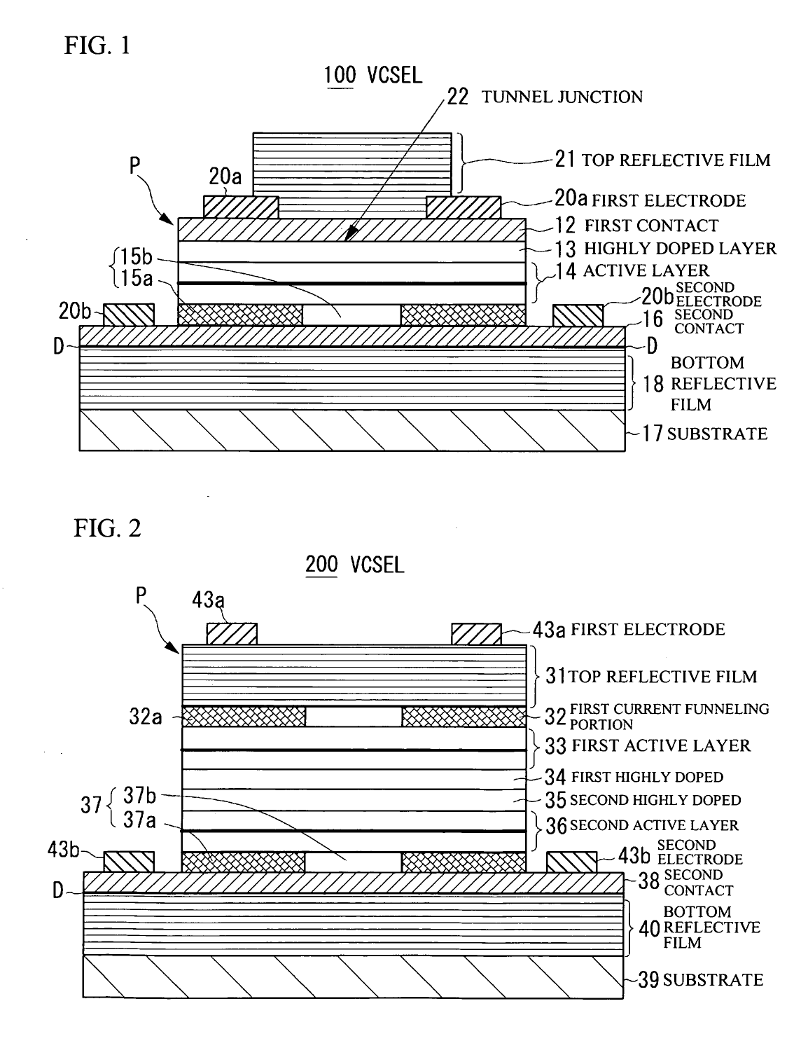

FIG. 1 is a cross-sectional view of a VCSEL in accordance with a first embodiment of the present invention. Referring to FIG. 1, a VCSEL 100 in accordance with the first embodiment of the present invention includes an undoped semiconductor substrate 17. On the semiconductor substrate 17, there are successively provided from the bottom, an undoped bottom reflective film 18 composed of semiconductor multiple films of GaAs/AlGaAs, an n-type second contact layer 16, an n-type current funneling layer 15 that includes a layer having high concentration of aluminum, an active region 14 composed of undoped spacer layers and a quantum well active layer disposed therebetween, a highly doped layer 13 with p-type high impurity concentration, a first contact layer 12 with n-type high impurity concentration, and a top reflective film 21 composed of dielectric multiple films of TiO₂/SiO₂. The top and bottom reflective films 18 and 21 serve as DBRs (Distributed Bragg Reflectors). The current funneling layer is a current confinement layer.

A cylinder-shaped post P is formed on the second contact layer 12 from the second contact layer 12 through the current funneling layer 15. The current funneling layer 15 and the second contact layer 16 are provided closer to the bottom reflective film 18, viewing from the active region 14. The current funneling layer 15 includes a semiconductor film with an extremely high relative proportion of aluminum, and includes an oxidized region 15a, which is oxidized from the side face of the post in the thermal treatment process. The oxidized region 15a has a shape that reflects an outer shape of the post. In the oxidized region 15a, an opening 15b of non-oxidized and conductive region is formed. The current funneling layer 15 defines the light emitting region of the laser beams and forms a current funneling region.

Ring-shaped first and second electrodes 20a and 20b are respectively provided on the first contact layer 12 and the second contact layer 16 so as to establish the electric contact and serve as intracavity contacts. The VCSEL 100 in accordance with the present embodiment of the present invention, as will de described, the semiconductor layers respectively deposited on two substrates are bonded together by the substrate fusion bonding. A line D denotes a substrate fusion bonded region, in which the two substrates are bonded by the substrate fusion bonding.

In accordance with the present embodiment of the present invention, in the cylinder-shaped post P, a tunnel junction region 22 is formed by the highly doped layer 13 in which the high concentration of p-type impurities are doped and the first contact layer 12 in which the n-type impurities are doped. The highly doped layer 13 and the first contact layer 12 are adjacently arranged to each other. The tunnel junction region 22 is interposed between the active region 14 and the top reflective film 21. The current funneling layer 15 is interposed between the active region 14 and the bottom reflective film 18. That is to say, the tunnel junction region 22 and the current funneling layer 15 are provided apart from each other, but sandwich the active region 14. With such structure, even if the dopant is diffused from the semiconductor layers with high impurity concentration that forms the tunnel junction region 22, the dopant can be mostly absorbed in the undoped active region 14 and can prevent the dopant from diffusing into the current funneling layer 15. This results in the suppression of the variations in the oxidized region 15a in the current funneling layer 15, namely, the variations of the diameter of the opening 15b surrounded by the oxidized region 15a. This makes it possible to stabilize the characteristics of the laser device.

Drive voltages are applied to the first electrode 20a positively charged and the second electrode 20b negatively charged, and then a tunneling current flows across the tunnel junction region 22. At this point, the tunneling current is confined in the lateral direction by the oxidized region 15a, and accordingly electron-dense tunneling currents are injected into the active region 14. In response to this, the laser beam is generated from the active region 14, and is emitted from the top reflective film 21 via the opening in the center of the first electrode 20a.

FIG. 2 is a cross-sectional view of the VCSEL in accordance with a second embodiment of the present invention. A VCSEL 200 in accordance with the second embodiment of the present invention includes multiple active regions provided in the post P formed on the substrate. There are provided on a semiconductor substrate 39 of GaAs, successively from the bottom, an undoped bottom reflective film 40 of semiconductor multiple films of GaAs/AlGaAs, an n-type contact layer 38, a second n-type current funneling layer 37, a second active region 36, a second highly doped layer 35 with p-type high impurity concentration, a first highly doped layer 34 with n-type high impurity concentration, a first active region 33, a first n-type current funneling layer 32, a n-type top reflective film 31 composed of multiple films of InP/InGaAsP.

A cylinder-shaped post P is formed on the second contact layer 38 from the top reflective film 31 through the second current funneling layer 37. Ring-shaped first and second electrodes 43a and 43b are respectively provided on the top reflective film 31 and the second contact layer 38 so as to establish the electric contact. The VCSEL 200 in accordance with the second embodiment of the present invention employs the top reflective film 31, one of the reflective films, as a current path, which is different from the VCSEL 100 in accordance with the first embodiment of the present invention.

A tunnel junction region 41 is formed with the first highly doped layer 34 and the second highly doped layer 35. The first active region 33 and the second active region 36 sandwich the tunnel junction region 41, and are connected in series in a direction perpendicular to the substrate. In addition, the first current funneling layer 32 is arranged close to the first active region 33, and the second first current funneling layer 37 is arranged close to the second active region 36. The first current funneling layer 32 and the first active region 33 are arranged on an opposite side of the second first current funneling layer 37 and the second active region 36, viewing from the tunnel junction region 41 that is sandwiched between the active regions 33 and 36. That is to say, there are successively arranged in series in the following order, the first current funneling layer 32, the first active region 33, the tunnel junction region 41, the second active region 36, and the second current funneling layer 37.

In the afore-mentioned arrangement, the tunnel junction region 41 is not adjacently arranged to either the first current funneling layer 32 or the second current funneling layer 37. It is to be noted that the tunnel junction region 41 is provided apart from either the first current funneling layer 32 or the second current funneling layer 37. The tunnel junction region 41 is sandwiched between the first and second active regions 33 and 36. If the dopant of concentrated impurities in the tunnel junction region 41 is diffused, the first and second current funneling layers 32 and 37 can be prevented from being affected by the dopant. This is the reason the constant repeatability can be maintained in oxidized regions 32a and 37a in the first and second current funneling layers 32 and 37.

The VCSEL 200 in accordance with the second embodiment of the present invention is configured to provide one tunnel junction region 41 between two active regions 33 and 36, and two current funneling layers 32 and 37 sandwich the active regions 33 and 36. In addition to this configuration, it is possible to provide one current funneling layer interposed between the two active regions 33 and 36, and two tunnel junction regions are provided to sandwich the active regions 33 and 36. Furthermore, three active regions may be provided in the post. In this case, there may be provided on the substrate from the bottom, the current funneling layer, the active region, the tunnel junction region, the active region, the current funneling layer, the active region, and the tunnel junction region. Alternatively, there may be provided on the substrate from the bottom, the tunnel junction region, the active region, the current funneling layer, the active region, the tunnel junction region, the active region, and the current funneling layer.

A description will now be given of the VCSELs 1 and 2 in accordance with the first and second embodiments of the present invention. In the following description, the names of materials will be represented as chemical sign, atomic symbol, or chemical formula.

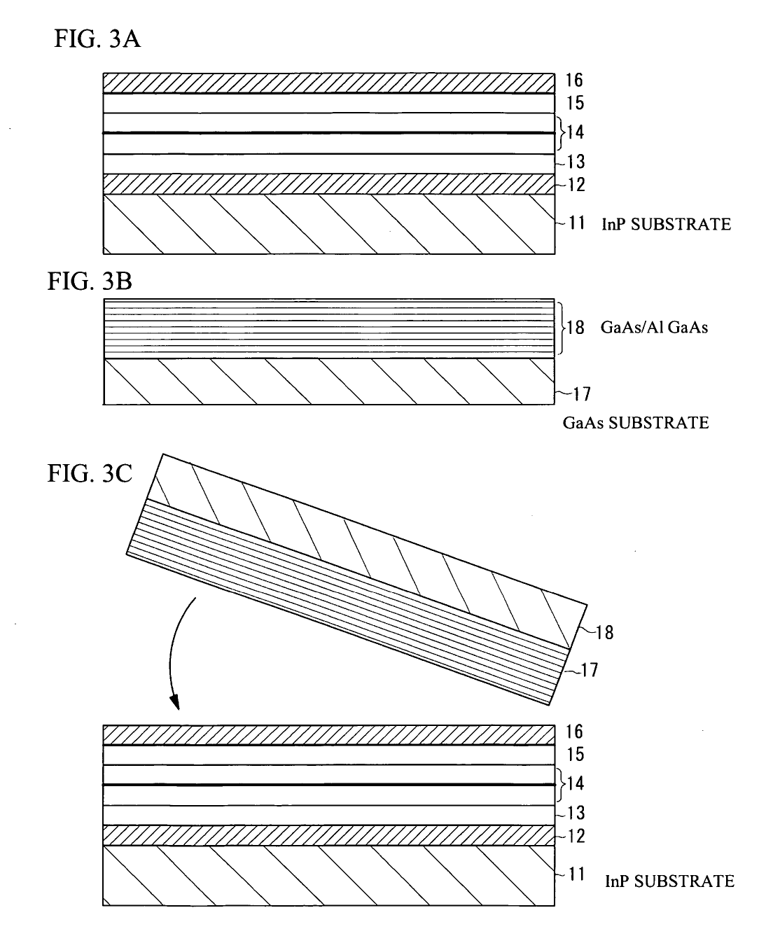

FIGS. 3A through 5C are cross-sectional views illustrating a configuration and fabrication processes of the VCSEL 100 in accordance with the first embodiment of the present invention. First, referring to FIG. 3A, with the use of the molecular beam epitaxy (MBE), on an undoped InP substrate 11, there are sequentially deposited the first contact layer 12 of n-type InP layer, the highly doped layer 13 of p++type InGaAsP layer, the active region 14 made up with the spacer layers of undoped InGaAsP layers and the quantum well active layer, the layer 15 of n-type Al_{0.48}In_{0.52}As layer, and the second contact layer 16 of n-type InP layer.

Here, it is configured that the Si-doped n-type InP layer has a carrier density of 5×10¹⁹ cm⁻³, Be-doped P⁺⁺ type InGaAsP layer has that of 1×10²⁰ cm⁻³, Si-doped n-type Al_{0.48}In_{0.52}As layer has that of 3×10¹⁸ cm⁻³, and Si-doped n-type InP layer has that of 5×10¹⁸ cm⁻³.

The active region 14 includes the quantum well layer of undoped InGaAsP layer (λg=1.31 μm) and barrier layers of undoped InGaAsP layer (λg=1.2 μm), which are alternately deposited so that the quantum well layer is sandwiched by the barrier layers and such sandwiched quantum well layer and the barrier layers are interposed by the spacer layers of undoped InGaAsP layer (λg=1.1 μm) so that the total film thickness is an integral multiple of λ/nᵣ.

Subsequently, referring to FIG. 3B, 35.5 periods of the semiconductor multiple films 18 are deposited on the undoped GaAs substrate 17 by the MBE method. The semiconductor multiple films 18 are made up with undoped GaAs layers and undoped Al_{0.9}Ga_{0.1}As layers. Each layer included in the semiconductor multiple films 18 corresponds to λ/4nᵣ (where λ denotes an oscillation wavelength and nr denotes an optical refractive index in the medium).

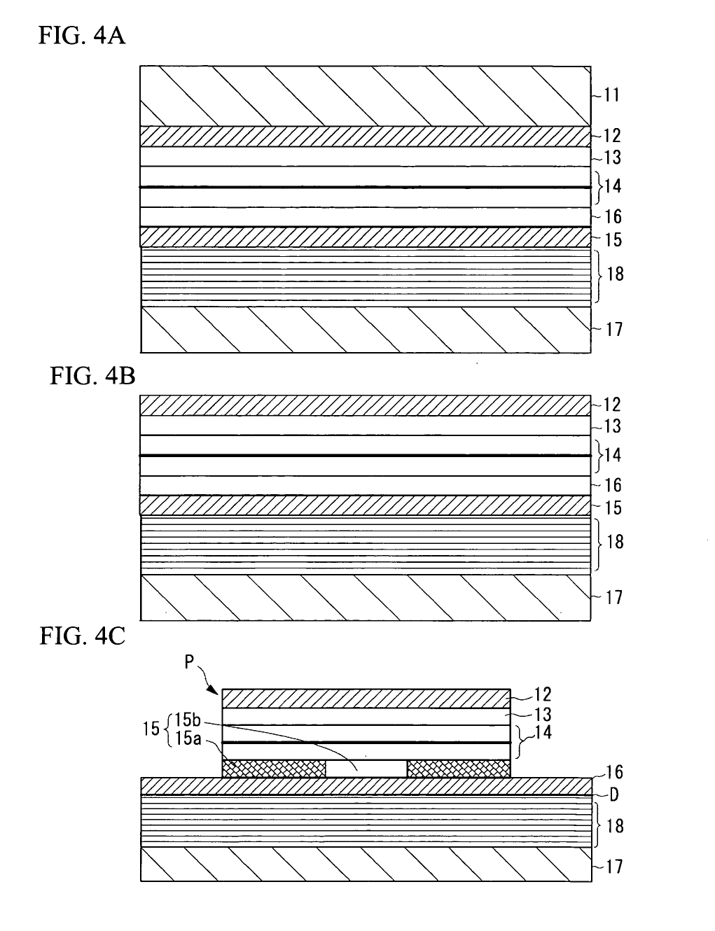

Referring now to FIG. 3C, the multiple films deposited on the InP substrate 11 and the multiple films deposited on the undoped GaAs substrate 17 are bonded together, and then the thermal treatment is carried out at 600 to 650 degrees C. for approximately one hour in hydrogen atmosphere. In this process, the substrates are thermally bonded together. Referring now to FIG. 4A, the VCSEL substrate is fabricated in the fusion bonding to be sandwiched by the InP substrate 11 and the GaAs substrate 17.

Next, referring to FIG. 4B, when the active region 14 of InGaAsP is deposited, the InP substrate 11 used as a supporting substrate is etched and removed. An extremely thin n-type InGaAsP layer, not shown, is inserted to be used as an etch stop layer, between the undoped InP substrate 11 and the first contact layer 12 of n-type InP layer.

Now, referring to FIG. 4C, the first contact layer 12, the highly doped layer 13, the active region 14, and the layer 15 of Al_{0.48}In_{0.52}As layer are respectively selectively etched and removed with the second contact layer 16 used as the etch stop layer, so as to have a shape of column (post) having a diameter of 50 μm. The etch stop layer uniquely defines the etch depth, and the layer 15 of Al_{0.48}In_{0.52}As is exposed as a part of a side face of the post P.

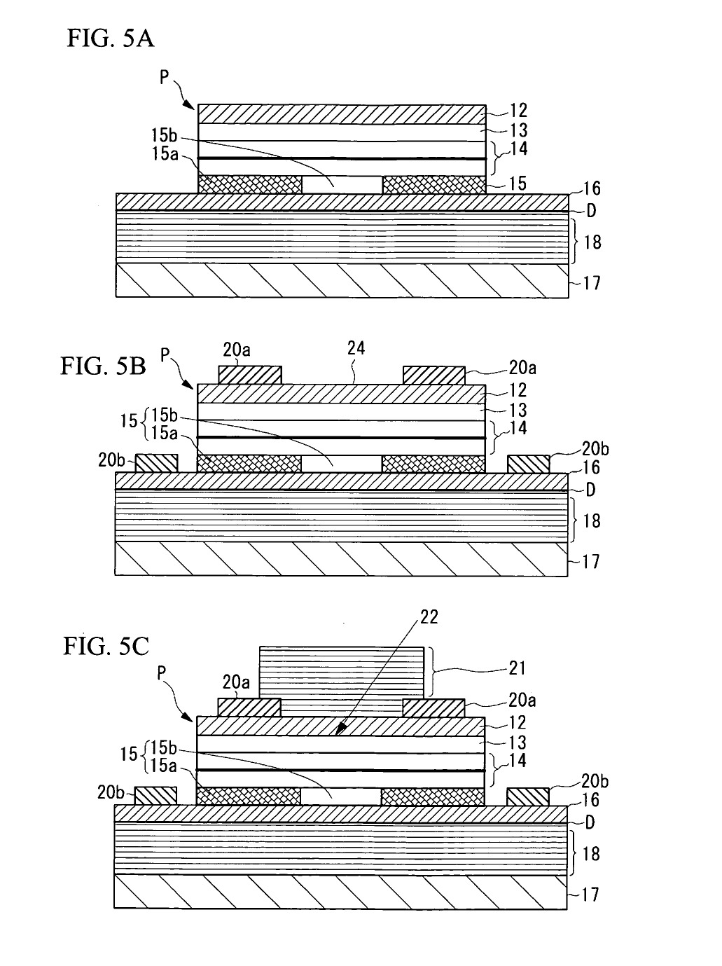

Subsequently, the substrate is exposed to water vapor atmosphere at 450 degrees C. with a carrier gas of nitrogen (flow volume: 2 litters/minute) for approximately one hour. At this point, the Al_{0.48}In_{0.52}As layer has an oxidation rate faster than other layers exposed as the side face of the post P. Therefore, as shown in FIG. 5A, a substantially circle-shaped non-oxidized region 15b, which reflects an outer shape of the post is formed immediately below the active region 14 in the post P.

The conductivity is degraded in the oxidized region 15a, making the oxidized region 15a function as the current funneling region. At the same time, the optical refractive index thereof is approximately half (up to 1.6) the index of the neighboring semiconductor layer. Hence, the oxidized region 15a also serves as an optical funneling region. The non-oxidized region (conductive region) 15b serves as a current path (carrier passing region).

Subsequently, referring to FIG. 5B, the ring-shaped contact electrodes 20a and 20b of two-layered structure having titanium and gold (Ti/Au) are respectively formed on the top of the post to establish electric contact with the first contact layer 12 and on the bottom of the post to establish electric contact with the second contact layer 16.

The first electrode 20a, in particular, has an opening 24 arranged in the center having an inner diameter of 20 μm so as to emit the laser beams from the top surface of the post. Further, extensional wires or pads, not shown, may be provided on the contact electrodes 20a and 20b to facilitate the mounting a VCSEL device on a stem or the like.

Next, as shown in FIG. 5C, the dielectric multiple films 21 having multiple layers of TiO₂ and SiO₂ are deposited on the top of the post by the lift-off method to cover the opening arranged in the center of the ring-shaped first electrode 20a. The top reflective film is thus formed to obtain the VCSEL 100 in accordance with the first embodiment of the present invention as shown in FIG. 1.

In accordance with the present embodiment of the present invention, the highly doped layer 13 of the p++type InGaAsP layer is interposed between the first contact layer 12 of n-type InP layer and the second contact layer 16 of the n-type InP layer. The tunnel junction region 22 is formed in an interface between the highly doped layer 13 and the first contact layer 12. Therefore, when the voltages are applied to the first contact layer 12 positively charged and the second contact layer 16 negatively charged, the tunneling current varying depending on such applied voltage values flows across the first contact layer 12 and the second contact layer 16.

The current funneling layer 15 having a high relative proportion of aluminum is arranged in the opposite of the tunnel junction region 22. The active region 14 is interposed between the tunnel junction region 22 and the current funneling layer 15, and the current funneling layer 15 is partially oxidized from the periphery in the thermal treatment to form a high-resistivity region. This confines the tunneling current. In addition, the oxidized region 15a is degraded in the refractive index, producing the light funneling effect to the light emitting region.

In this manner, the tunnel junction region and the current funneling region sandwich the active region, but are arranged apart from each other. Even if the impurities are partially diffused into the neighboring semiconductor layers from the highly doped layer having concentrated impurities to be doped for forming the tunnel junction region, such diffused impurities will not reach the current funneling region after passing through the undoped active region.

Therefore, it is possible to avoid uniform characteristics caused by the variations in the diameter of the opening provided in the current funneling region, whereas such variations are often seen in the VCSELs with the tunnel junctions. It is possible to obtain the long-wavelength VCSEL device with high repeatability and stability.

Next, a description will be given of the VCSEL 200 in accordance with the second embodiment of the present invention. Most fabrication processes are same as those of the VCSEL 100 in accordance with the first embodiment, so a description will be partially omitted. The semiconductor multiple films 31, which is a laminated body of multiple n-type InP layers and InGaAsP layers, are deposited on the n-type InP substrate. Each layer has a thickness of λ/4nᵣ.

Then, there are sequentially deposited the first current funneling layer 32, the first active region 33, the first highly doped layer 34, the second highly doped layer 35, the second active region 36, the second current funneling layer 37, and the contact layer 38. The first current funneling layer 32 has a high relative proportion of aluminum of n-type Al_{0.48}In_{0.52}As layer. The first active region 33 is made up with the spacer layer of undoped InGaAsP layer and the quantum well active layer. The first highly doped layer 34 is composed of the n⁺⁺ type InGaAsP layer. The second highly doped layer 35 is composed of the p++type of InGaAsP layer. The second active region 36 is made up with the spacer layer of undoped InGaAsP layer and the quantum well active layer. The second current funneling layer 37 has a high relative proportion of aluminum of n-type Al_{0.48}In_{0.52}As layer. The contact layer 38 is composed of the n-type InP layer.

Here, it is configured that the Se-doped n-type Al_{0.48}In_{0.52}As layer has a carrier density of 3×10¹⁸ cm³, Se-doped n⁺⁺ InGaAsP layer has that of 1×10²⁰ cm⁻³, Zn-doped p⁺⁺ type InGaAsP layer has that of 5×10¹⁹ cm⁻³, and Se-doped n-type InP layer has that of 5×10¹⁹ cm⁻³.

On another undoped substrate 39 of GaAs, semiconductor multiple films 40 are deposited. The semiconductor multiple films 40 are a laminated body having multiple undoped GaAs layers and undoped Al_{0.9}Ga_{0.1}As layers. Each layer has a thickness of λ4nᵣ.

As in the VCSEL 100 in accordance with the first embodiment of the present invention, the two substrates are bonded together by the thermal bonding so that the second contact layer 38 faces the semiconductor multiple films 40.

The etch and oxidation processes are same as those of the VCSEL 100 in accordance with the first embodiment of the present invention. The first current funneling layer (the layer having a high relative proportion of aluminum) 32 composed of n-type Al_{0.48}In_{0.52}As layer and the second current funneling layer (the layer having a high relative proportion of aluminum) 37 has the oxidation rate faster than other layers. Therefore, the first oxidized region 32a and the second oxidized region 37a are formed in the periphery of the post, and the conductive regions 32b and 37b, which are non-oxidized regions, are formed in the center of the post.

The ring-shaped contact electrodes 43a and 43b of two-layered structure having titanium and gold (Ti/Au) are respectively formed on the top of the post to establish electric contact with the semiconductor multiple films 31 and on the bottom of the post to establish electric contact with the contact layer 38.

As described, the tunnel junction region 41 is formed in the interface between the first highly doped layer 34 of n++type InGaAsP layer and the second highly doped layer 35 of p⁺⁺ InGaAsP layer. When voltages are applied to the semiconductor multiple films 31 positively charged and located on the upper side and the contact layer 38 negatively charged located on the lower side, the tunneling current that varies depending on the voltage values flows across the semiconductor multiple films 31 and the contact layer 38. Then, the carriers are injected into the first active region 33 and the second active region 36 respectively.

With respect to the peripherals of the first active region 33 and the second active region 36, the first oxidized region 32a and the second oxidized region 37a respectively form high-resistivity regions, and the tunneling current is confined. The oxidized regions are degraded in the refractive index, producing the light funneling effect to the light emitting region.

On a cascade type of VCSEL having multiple active regions, at least one active region is interposed by the tunnel junction region and the current funneling region. This makes it possible to produce the long-wavelength VCSEL device with a high repeatability in view of process and characteristics.

In the first embodiment, the column-shaped post P is formed, and then, the oxidation and electrode formation processes are completed. However, the shape of the post P is not related to a true nature of the present invention. Therefore, a shape of square column may be employed and an arbitrary shape is applicable within the scope of the principle of operation of the present invention.

Also in the first embodiment, a combination of TiO₂/SiO₂ is employed for the material that forms the dielectric multiple films. However, the present invention is not limited to the aforementioned materials, for example, ZnO, MgO, Al₂O₃, or the like is applicable. Also, silicon may be employed.

Furthermore, the first and second embodiments of the present invention exemplify the InGaAsP-based compound semiconductor lasers. In addition, the semiconductor laser that includes a gallium nitride-based material or indium gallium arsenide-based material is applicable. In accordance with the material to be employed, the oscillation wavelength may be changed as necessary.

The first embodiment of the present invention exemplifies that one of the top and bottom reflective films is composed of the semiconductor multiple films and the other is composed of dielectric multiple films. The second embodiment exemplifies that both of the top and bottom reflective films are composed of semiconductor multiple films. However, the present invention is not limited to the afore-mentioned examples. It is possible to form both of the reflective films with the dielectric multiple films, although the reflective film of the dielectric multiple films cannot function as the current path.

In the second embodiment, the top reflective film is composed of the semiconductor multiple films to exemplify the top reflective film serving as the electric path. When the bottom reflective film is also composed of the semiconductor multiple films, it is possible to make both the top and bottom reflective films function as the electric paths. However, if the InGaAsP-based active layer is employed, it will be difficult to obtain high reflectance with the material lattice matched to the InP substrate, as described above. Therefore, even if the top and bottom reflective films are made of the semiconductor multiple films, both the top and bottom reflective films do not have to serve as the electric paths.

Alternatively, when the semiconductor multiple films other than the lattice matched material are bonded in the substrate fusion method, it is not easy to let the carriers pass through the interface effectively, yet in principle, it is not impossible to design the interface to serve as the electric path.

In the embodiments of the present invention, an undoped active region is interposed between the tunnel junction region and the current funneling region so that the tunnel junction region and the current funneling region may not be adjacently arranged to each other in the laminated structure. It is therefore possible to eliminate the influence of the impurities diffused from the highly doped layer, which is provided for forming the tunnel junction.

In the second embodiment, there are exemplified one tunnel junction region and two oxidized regions (current funneling regions), yet for example, there may be considered a combination of two tunnel junction regions and one oxidized region (current funneling region) and another combination of two tunnel junction regions and two oxidized regions (current funneling regions).

Lastly, although a few embodiments of the present invention have been shown and described, it would be appreciated by those skilled in the art that changes may be made in these embodiments without departing from the principles and spirit of the invention, the scope of which is defined in the claims and their equivalents.

Next, a description will be given of an example the VCSEL in accordance with the present invention is applied as a light source. The VCSEL can be used as the light source in a single laser device, yet multiple laser devices mounted on the substrate can be used as a parallel light source.

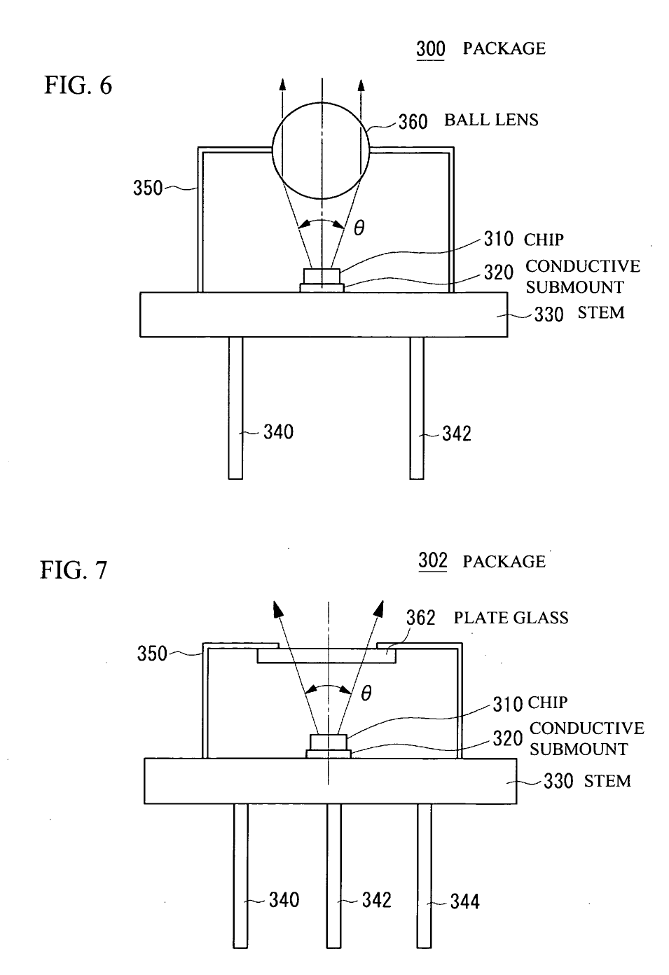

FIG. 6 is a cross-sectional view of a VCSEL chip, which is incorporated into a package (optical module). Referring to FIG. 6, a package 300 includes a chip 310 having the VCSEL. The chip 310 is secured onto a disc-shaped metal stem 330 with a conductive submount 320. Conductive leads 340 and 342 are inserted into through-bores, not shown, provided in the stem 330. The lead 340 is electrically connected to the first electrode formed on the backside of the chip 310, and the lead 342 is electrically connected to the second electrode formed on the surface of the chip 310 with a bonding wire or the like.

A rectangle-shaped hollow cap 350 is secured onto the step 330 having the chip 310 thereon, and a ball lens 360 is secured in an opening arranged in the center of the cap 350. A light axis of the ball lens 360 is positioned to approximately correspond to the center of the chip 310. A forward voltage is applied to the leads 340 and 342, and then the laser beams are emitted from the mesa of the chip 310. The distance between the chip 310 and the ball lens 360 is adjusted so that the ball lens 360 may be included within an emitting angle θ of the laser beams emitted from the chip 310. A light receiving element may be included in the cap 350 so as to monitor an emitting state of the VCSEL.

FIG. 7 shows another package configuration, which may be used for a space transmission system, as will be described later. A package 302 shown in FIG. 7 includes a plate glass 362, instead of the ball lens 360. The plate glass 362 is secured in the opening arranged in the center of the cap 350. The center of the plate glass 362 is positioned to approximately correspond to the center of the chip 310. The distance between the chip 310 and the plate glass 362 is adjusted so that the diameter of the opening provided for the plate glass 362 may be greater than the emitting angle θ of the laser beams emitted from the chip 310.

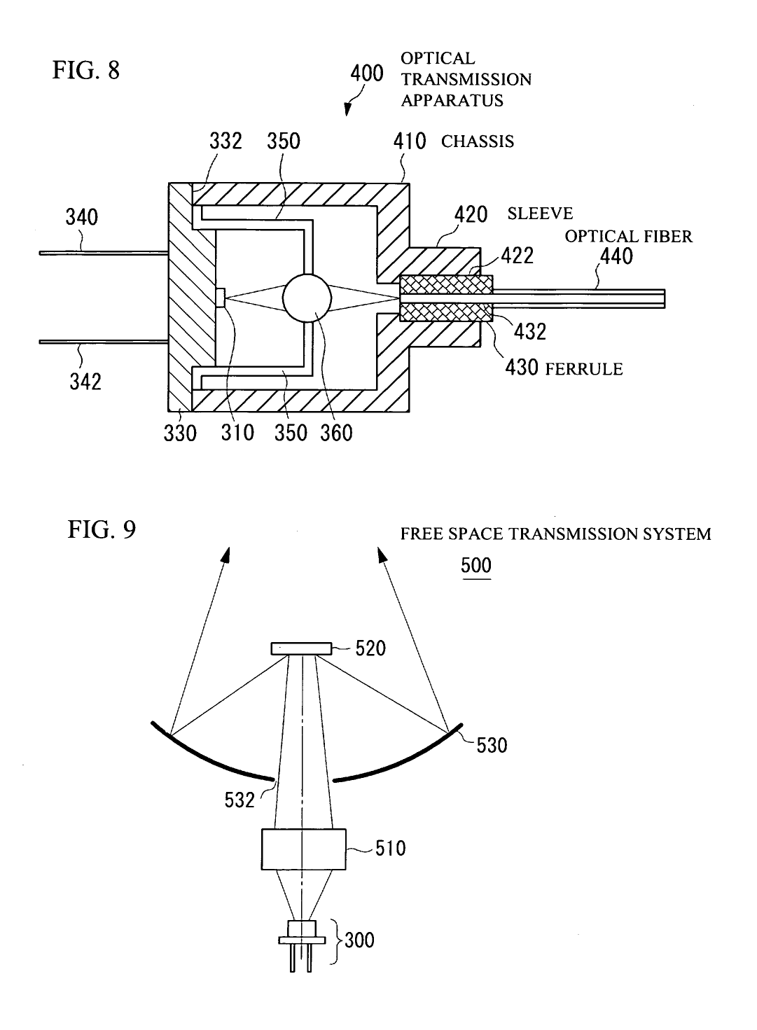

FIG. 8 is a cross-sectional view of an optical transmission apparatus to which the package or module shown in FIG. 6 is applied. An optical transmission apparatus 400 includes a chassis 410, a sleeve 420, a ferrule 430, and an optical fiber 440. The chassis 410 is cylinder-shaped and secured to the stem 330. The sleeve 420 is formed together with the chassis 410 on edges of the chassis 410 as one member. The ferrule 430 is retained inside an opening 422 of the sleeve 420. The optical fiber 440 is retained by the ferrule 430.

An edge of the chassis 410 is secured to a flange 332 formed in a circumference direction of the stem 330. The ferrule 430 is accurately positioned in the opening 422 of the sleeve 420, and the light axis of the optical fiber 440 is aligned with the light axis of the ball lens 360. A cable core of the optical fiber 440 is retained in a through-bore 432 of the ferrule 430.

The laser beams emitted from the surface of the chip 310 are focused by the ball lens 360. Such focused beams are entered into the cable core of the optical fiber 440, and are then transmitted. In the above-mentioned example, the ball lens 360 is employed, yet other than that, another type of lens such as a convexo-convex lens, plano-convex lens, or the like may be employed. In addition, the optical transmission apparatus 400 may include a drive circuit to apply electric signals to the leads 340 and 342. The optical transmission apparatus 400 may include a receiving device to receive optical signals via the optical fiber 440.

FIG. 9 is a view illustrating a configuration of a space transmission system to which the package or module shown in FIG. 7 is applied. A space transmission system 500 includes the package 300, a collective lens 510, a diffuser 520, and a reflection mirror 530. The space transmission system 500 utilizes the collective lens 510, instead of the ball lens 360 used in the package 300. The lights collected by the collective lens 510 are reflected by the diffuser 520 via an opening 532 provided in the reflection mirror 530. Such reflected lights are emitted toward the reflection mirror 530. Such reflected lights are then reflected by the reflection mirror 530 toward given directions, for optical transmission. A multi-spot VCSEL may be employed as the light source in the space transmission for high outputs.

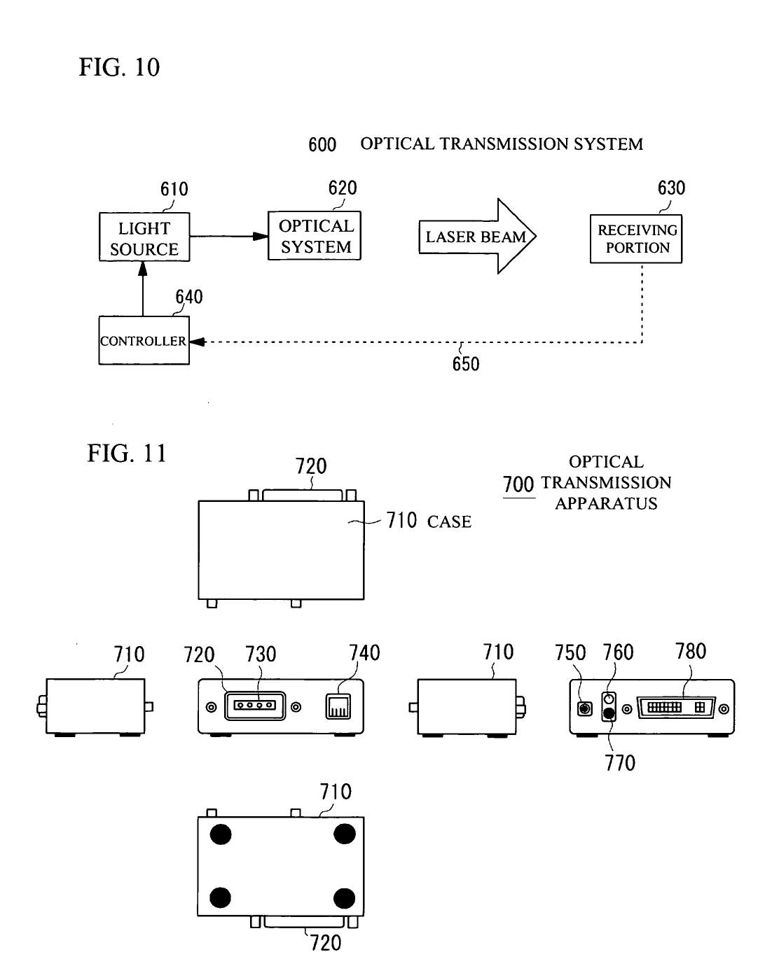

FIG. 10 is a view illustrating a configuration of the optical transmission system to which the VCSEL is used as the light source. An optical transmission system 600 includes a light source 610, an optical system 620, a receiving portion 630, and a controller 640. The light source 610 includes the chip 310 having the VCSEL. The optical system 620 collects the laser beams emitted from the light source 610. The receiving portion 630 receives the laser beams emitted from the optical system 620. The controller 640 controls to drive the light source 610. The controller 640 supplies driving pulse signals to the light source 610 so as to drive the VCSEL. The light emitted from the light source 610 passes through the optical system 620, and is transmitted to the receiving portion 630 via the optical fiber, the reflection mirror used for the space transmission, and the like. The receiving portion 630 detects the light received with a photodetector or the like. The receiving portion 630 is capable of controlling the operation of the controller 640, for example, a timing to start the optical transmission, with a control signal 650.

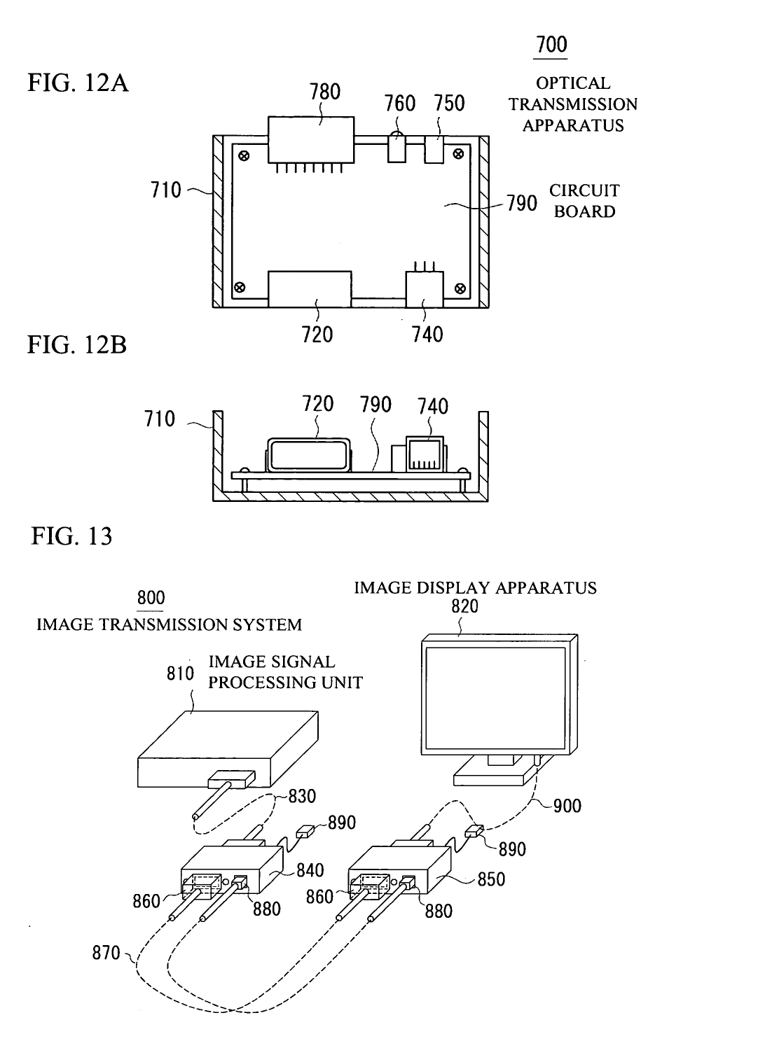

Next, a description will be given of the configuration of the optical transmission apparatus used for the optical transmission system. FIG. 11 is a view illustrating an appearance of the optical transmission apparatus. FIGS. 12A and 12B schematically show internal configurations. An optical transmission apparatus 700 includes a case 710, an optical signal transmitting/receiving connector connection portion 720, a light emitting/receiving element 730, an electric signal cable connection portion 740, a power source input portion 750, an LED 760 that indicates active, another LED 770 that indicates something wrong, a DVI connector 780, and a transmitting circuit board/receiving circuit board 790.

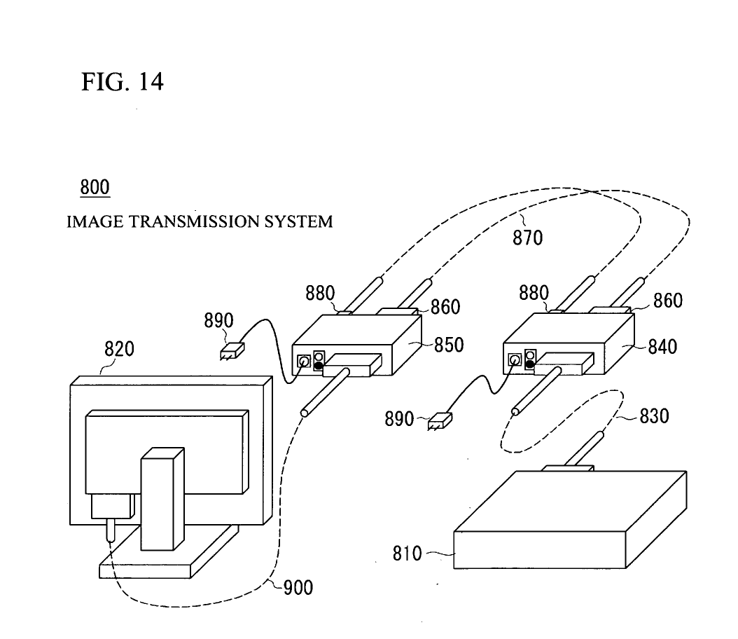

FIGS. 13 and 14 show image transmission systems with the use of the optical transmission apparatus 700. In these drawings, an image transmission system 800 utilizes the optical transmission apparatus shown in FIG. 8 so as to transmit image signals generated by an image signal processing unit 810 to an image display apparatus 820 such as a crystal liquid display. That is to say, the image transmission system 800 includes the image signal processing unit 810, the image display apparatus 820, an electric cable for DVI 830, a transmitting module 840, a receiving module 850, a connector for image signal transmission 860, an optical fiber 870, an electric cable connector for image signal transmission 880, a power adaptor 890, and an electric cable for DVI 900.

In the afore-mentioned image transmission system, the image signal processing unit 810 and the transmitting module 840 are connected with the electric cable 830, and the receiving module 850 and the image display apparatus 820 are connected with the electric cable 900. However, the optical signals may transmit between the afore-mentioned components. For example, the electric cables 830 and 900 may be replaced by cables for signal transmission having connectors in which an electricity-light conversion device and a light-electricity conversion device are included.

It is therefore possible to arrange the surface emitting semiconductor laser diode of a tunnel junction type in accordance with the present invention on a semiconductor substrate solely or in a two-dimensional array for optical information processing and high-speed data transmission.

According to the present invention, the active region is interposed by the tunnel junction region and the current funneling region. This prevents the VCSEL device from degrading the repeatability of the production process, enabling stable characteristics with few variations. The degradation is caused by, for example, the diffusion of the dopant of high impurity concentration in the tunnel junction region into the adjacently arranged semiconductor layer after the heat is generated in forming the current funneling region or in other processes.

In addition, on the cascade type of VCSEL having multiple active regions, the current funneling region and the tunnel junction region sandwich the active region in a direction vertical to the substrate. In other words, one active region is always interposed by the current funneling region and the tunnel junction region. This prevents the VCSEL device from degrading the repeatability of the production process, enabling stable characteristics with few variations, as seen in the VCSEL having a single active region.

On the above-mentioned surface emitting semiconductor laser diode, the first reflective film (the bottom reflective film) includes either semiconductor multiple reflective films or dielectric multiple films, and the second reflective film (the top reflective film) includes either the semiconductor multiple reflective films or the dielectric multiple films. At least one of the reflective films may be composed of GaAs-based semiconductor multiple films.

Although a few embodiments of the present invention have been shown and described, it would be appreciated by those skilled in the art that changes may be made in these embodiments without departing from the principles and spirit of the invention, the scope of which is defined in the claims and their equivalents.

The entire disclosure of Japanese Patent Application No. 2005-175433 filed on Jun. 15, 2005 including specification, claims, drawings, and abstract is incorporated herein by reference in its entirety.

What is claimed is:

1. A surface emitting semiconductor laser diode comprising:
a semiconductor substrate;
a first reflective film provided on the semiconductor substrate;
a second reflective film provided above the first reflective film;
an active region;
a tunnel junction region; and
a current funneling layer,
wherein the active region, the tunnel junction region, and the current funneling layer are provided in series between the first and second reflective films, the active region being interposed by the tunnel junction region and the current funneling layer.

2. The surface emitting semiconductor laser diode according to claim 1, wherein the tunnel junction region is provided above the first reflective film, the active region is provided on the tunnel junction region, and the current funneling layer is provided on the active region.

3. The surface emitting semiconductor laser diode according to claim 1, wherein the current funneling layer is provided above the first reflective film, the active region is provided on the current funneling layer, and the tunnel junction region is provided on the active region.

4. The surface emitting semiconductor laser diode according to claim 1, further comprising:
multiple active regions connected in series between the first and second reflective films;
at least one current funneling layer; and
at least one tunnel junction region,
wherein said multiple active regions are respectively interposed by said at least one current funneling layer and said at least one tunnel junction region.

5. The surface emitting semiconductor laser diode according to claim 4, wherein each of said multiple active regions is interposed by either the tunnel junction region or the current funneling layer.

6. The surface emitting semiconductor laser diode according to claim 4, wherein the tunnel junction region is interposed by said multiple active regions.

7. The surface emitting semiconductor laser diode according to claim 1, wherein the tunnel junction region includes a first semiconductor layer of a first conductive type with high impurity concentration and a second semiconductor layer of a second conductive type with the high impurity concentration.

8. The surface emitting semiconductor laser diode according to claim 1, further comprising a contact layer that is electrically connected to an electrode and forms the tunnel junction region.

9. The surface emitting semiconductor laser diode according to claim 1, wherein:
the first reflective film includes either semiconductor multiple reflective films or dielectric multiple films; and
the second reflective film includes either the semiconductor multiple reflective films or the dielectric multiple films.

10. The surface emitting semiconductor laser diode according to claim 1, wherein a post is formed on the semiconductor substrate and the post includes at least the current funneling region.

11. The surface emitting semiconductor laser diode according to claim 10, the current funneling region includes an oxidized region oxidized from a side face thereof.

12. The surface emitting semiconductor laser diode according to claim 11, further comprising;
a first electrode on a top of the post; and
a second electrode on a bottom of the post,
wherein a tunneling current flows across the tunnel junction region when voltages are applied to the first and second electrodes.

13. A module having a surface emitting semiconductor laser diode comprising:
a semiconductor substrate;
a first reflective film provided on the semiconductor substrate;
a second reflective film provided above the first reflective film;
an active region;
a tunnel junction region; and
a current funneling layer,
wherein the active region, the tunnel junction region, and the current funneling layer are provided in series between the first and second reflective films, the active region being interposed by the tunnel junction region and the current funneling layer.

14. An optical transmission apparatus comprising:
a module; and
a transmission device that transmits a laser beam emitted from the module,
the module having a surface emitting semiconductor laser diode that includes a semiconductor substrate, a first reflective film provided on the semiconductor substrate, a second reflective film provided above the first reflective film, an active region, a tunnel junction region, and a current funneling layer,
wherein the active region, the tunnel junction region, and the current funneling layer are provided in series between the first and second reflective films, the active region being interposed by the tunnel junction region and the current funneling layer.

15. A free space optical transmission apparatus comprising:
a module; and
a transmission device that transmits a light emitted from the module,
the module having a surface emitting semiconductor laser diode that includes a semiconductor substrate, a first reflective film provided on the semiconductor substrate, a second reflective film provided above the first reflective film, an active region, a tunnel junction region, and a current funneling layer,
wherein the active region, the tunnel junction region, and the current funneling layer are provided in series between the first and second reflective films, the active region being interposed by the tunnel junction region and the current funneling layer.

16. An optical transmission system comprising:
a module; and
a transmission device that transmits a laser beam emitted from the module,
the module having a surface emitting semiconductor laser diode that includes a semiconductor substrate, a first reflective film provided on the semiconductor substrate, a second reflective film provided above the first reflective film, an active region, a tunnel junction region, and a current funneling layer,
wherein the active region, the tunnel junction region, and the current funneling layer are provided in series between the first and second reflective films, the active region being interposed by the tunnel junction region and the current funneling layer.

17. A free space optical transmission system comprising:
a module; and
a transmission device that transmits a light emitted from the module,
the module having a surface emitting semiconductor laser diode that includes a semiconductor substrate, a first reflective film provided on the semiconductor substrate, a second reflective film provided above the first reflective film, an active region, a tunnel junction region, and a current funneling layer,
wherein the active region, the tunnel junction region, and the current funneling layer are provided in series between the first and second reflective films, the active region being interposed by the tunnel junction region and the current funneling layer.

18. A fabrication method of a surface emitting semiconductor laser diode having a semiconductor substrate, a first reflective film provided on the semiconductor substrate, a second reflective film provided above the first reflective film, an active region, a tunnel junction region, and a current funneling layer provided in series between the first reflective film and the second reflective film, the fabrication method comprising:
preparing first and second substrates, the first substrate having a semiconductor layer in which the tunnel junction region and the current funneling layer being respectively epitaxially grown to interpose the active region, the first reflective film being epitaxially grown on the second substrate;
bonding the first and second substrates so that the first reflective film faces the semiconductor layer;
removing the first substrate; and
forming the second reflective film on the semiconductor layer.

19. The fabrication method according to claim 18, further comprising:
forming a post on the semiconductor substrate by etching the semiconductor layer to expose at least a side face of the current funneling region after removing the first substrate;
partially oxidizing the current funneling region from the side face thereof; and
forming electrodes to inject carriers into the tunnel junction region.

20. The fabrication method according to claim 19, wherein the electrodes include a first electrode formed on a top of the post and a second electrode formed on a bottom of the post.

21. The fabrication method according to claim 18, wherein the first substrate is a semiconductor substrate made of InP, and the second substrate is the semiconductor substrate made of GaAs.
